(19) United States
(12) Patent Application Publication
(10) Pub. No.: US 2026/0040775 A1
(43) Pub. Date: Feb. 5, 2026

(54) DISPLAY DEVICE, A METHOD OF MANUFACTURING THE DISPLAY DEVICE, AND ELECTRONIC DEVICE INCLUDING THE DISPLAY DEVICE

(71) Applicant: Samsung Display Co., LTD., Yongin-si (KR)

(72) Inventors: HYUN KIM, Yongin-si (KR); YEEUN KANG, Yongin-si (KR); KAP SOO YOON, Yongin-si (KR); Seohee Lee, Yongin-si (KR); JIN-WON LEE, Yongin-si (KR)

(21) Appl. No.: 19/199,748

(22) Filed: May 6, 2025

(30) Foreign Application Priority Data
Jul. 30, 2024 (KR) 10-2024-0101059

(51) Int. Cl. H10K 59/124; H10K 59/12

(52) U.S. Cl. CPC H10K 59/124; H10K 59/1201

(57) ABSTRACT

A display device includes a lower metal pattern located on a substrate, a first insulating layer covering the lower metal pattern, an active pattern located on the first insulating layer, a second insulating layer covering the active pattern, and a first electrode located on the second insulating layer. The first insulating layer defines a first hole exposing at least a portion of the lower metal pattern and including a first side surface forming a first angle with an upper surface of the lower metal pattern. The second insulating layer defines a second hole at least partially overlapping the first hole in a plan view and including a second side surface forming a second angle smaller than the first angle with an upper surface of the first insulating layer. The first electrode contacts the lower metal pattern through the first hole and the second hole.

This application claims priority to Korean Patent Application No. 10-2024-0101059, filed on Jul. 30, 2024, and all the benefits accruing therefrom under 35 U.S.C. § 119, the content of which in its entirety is herein incorporated by reference.

### BACKGROUND

### 1. Technical Field

The invention relates generally to a display device, a method of manufacturing the display device, and an electronic device including the display device and more particularly, to a display device providing visual information, a method of manufacturing the display device, and an electronic device including the display device.

### 2. Description of the Related Art

A display device is a device that displays an image for providing visual information to a user. Among display devices, an organic light emitting diode display device has recently attracted attention.

The display device may include an active pattern and an insulating layer covering the active pattern. A portion of the insulating layer may be removed to form a hole connecting the active pattern and a source electrode (or, a drain electrode). In a process of forming the hole, the active pattern may be over-etched.

### SUMMARY

Embodiments provide a display device with improved quality.

Embodiments provide a method of manufacturing the display device.

Embodiments provide an electronic device including the display device.

A display device, according to an embodiment, includes a lower metal pattern located on a substrate, a first insulating layer covering the lower metal pattern, an active pattern located on the first insulating layer, a second insulating layer covering the active pattern, and a first electrode.

In an embodiment, the first insulating layer may define a first hole exposing at least a portion of the lower metal pattern and including a first side surface forming a first angle with an upper surface of the lower metal pattern.

In an embodiment, the second insulating layer may define a second hole at least partially overlapping the first hole in a plan view and including a second side surface forming a second angle which is smaller than the first angle with an upper surface of the first insulating layer.

In an embodiment, the first electrode may contact the lower metal pattern through the first hole and the second hole.

In an embodiment, the second angle may be equal to or greater than about 0 degrees and equal to or less than about 70 degrees.

In an embodiment, the second insulating layer may define a third hole exposing at least a portion of the active pattern and including a third side surface forming a third angle which is smaller than the first angle with an upper surface of the active pattern.

In an embodiment, the third angle may be equal to or greater than about 0 degrees and equal to or less than about 70 degrees.

In an embodiment, the first electrode may contact the active pattern through the third hole.

In an embodiment, the second insulating layer may define a fourth hole exposing at least a portion of the active pattern, spaced apart from the third hole in the plan view, and including a fourth side surface forming a fourth angle which is smaller than the first angle with the upper surface of the active pattern.

In an embodiment, the fourth angle may be equal to or greater than about 0 degrees and equal to or less than about 70 degrees.

In an embodiment, the display device may further include a second electrode located on the second insulating layer, spaced apart from the first electrode in a plan view, and contacting the active pattern through the fourth hole.

In an embodiment, the second hole may have an inverted trapezoidal shape in which a width of a lower surface is smaller than a width of an upper surface in a cross-sectional view, and a width of the lower surface of the second hole may be greater than a width of the first hole.

In an embodiment, a method includes forming a lower metal pattern on a substrate, forming a first preliminary insulating layer covering the lower metal pattern on the substrate, forming an active pattern on the first preliminary insulating layer, forming a second preliminary insulating layer covering the active pattern on the first preliminary insulating layer, removing a portion of the first preliminary insulating layer and a portion of the second preliminary insulating layer to expose at least a portion of the lower metal pattern, removing a portion of the second preliminary insulating layer to expose at least a portion of the active pattern, and forming a first electrode contacting the lower metal pattern and the active pattern.

In an embodiment, the removing of the portion of the second preliminary insulating layer to expose at least the portion of the active pattern may be performed after the removing of the portion of the first preliminary insulating layer and the portion of the second preliminary insulating layer to expose at least the portion of the lower metal pattern.

In an embodiment, the removing of the portion of the first preliminary insulating layer and the portion of the second preliminary insulating layer to expose at least the portion of the lower metal pattern may include forming a photoresist layer on the second preliminary insulating layer, placing a mask including a transmitting area, a semi-transmitting area and a blocking area on the photoresist layer, exposing and developing the photoresist layer to form a photoresist pattern, and removing the portion of the first preliminary insulating layer and the portion of the second preliminary insulating layer through a dry etching process.

In an embodiment, while the removing of the portion of the first preliminary insulating layer and the portion of the second preliminary insulating layer is in progress, a portion of the second preliminary insulating layer overlapping the semi-transmitting area of the mask in a plan view may not be removed.

In an embodiment, the method may further include removing a portion of the photoresist pattern after the removing of the portion of first preliminary insulating layer and the portion of the second preliminary insulating layer to expose at least the portion of the lower metal pattern, before the removing the portion of the second preliminary insulating layer to expose at least the portion of the active pattern.

In an embodiment, the active pattern may not be etched during the removing of the portion of first preliminary insulating layer and the portion of the second preliminary insulating layer to expose at least the portion of the lower metal pattern.

An electronic device, according to an embodiment, includes a lower metal pattern located on a substrate, a first insulating layer covering the lower metal pattern, an active pattern located on the first insulating layer, a second insulating layer covering the active pattern, a first electrode, and a memory configured to store data information.

In an embodiment, the first insulating layer may define a first hole exposing at least a portion of the lower metal pattern and including a first side surface forming a first angle with an upper surface of the lower metal pattern.

In an embodiment, the second insulating layer may define a second hole at least partially overlapping the first hole in a plan view and including a second side surface forming a second angle which is smaller than the first angle with an upper surface of the first insulating layer.

In an embodiment, the first electrode may contact the lower metal pattern through the first hole and the second hole.

In an embodiment, the second angle may be equal to or greater than about 0 degrees and equal to or less than about 70 degrees.

In an embodiment, the second insulating layer may define a third hole exposing at least a portion of the active pattern and including a third side surface forming a third angle which is smaller than the first angle with an upper surface of the active pattern.

In an embodiment, the third angle may be equal to or greater than about 0 degrees and equal to or less than about 70 degrees.

In an embodiment, the first electrode may contact the active pattern through the third hole.

A display device, according to an embodiment, may include a lower metal pattern, a first insulating layer covering the lower metal pattern, an active pattern located on the first insulating layer, and a second insulating layer covering the active pattern. The first insulating layer may define a first hole exposing at least a portion of the lower metal pattern and including a first side surface forming a first angle with an upper surface of the lower metal pattern. In addition, the second insulating layer may define a second hole at least partially overlapping the first hole in a plan view and including a second side surface forming a second angle which is smaller than the first angle with an upper surface of the first insulating layer. In addition, the second insulating layer defines a third hole exposing at least a portion of the active pattern and including a third side surface forming a third angle which is smaller than the first angle with an upper surface of the active pattern.

Accordingly, in an embodiment, a thickness of a contact electrode contacting the lower metal pattern and the active pattern may be constant in the second hole and the third hole.

In addition, a method of manufacturing a display device, according to an embodiment, may include forming a first preliminary insulating layer covering the lower metal pattern on the substrate, forming a second preliminary insulating layer covering the active pattern on the first preliminary insulating layer, removing a portion of the first preliminary insulating layer and a portion of the second preliminary insulating layer to expose at least a portion of the lower metal pattern, removing a portion of the second preliminary insulating layer to expose at least a portion of the active pattern, and forming a first electrode (i.e., contact electrode) contacting the lower metal pattern and the active pattern. According to embodiments, the removing of the portion of the first preliminary insulating layer and the portion of the second preliminary insulating layer to expose at least the portion of the lower metal pattern may include forming a photoresist layer on the second preliminary insulating layer, placing a mask including a transmitting area, a semi-transmitting area and a blocking area on the photoresist layer, exposing and developing the photoresist layer to form a photoresist pattern, and removing the portion of the first preliminary insulating layer and the portion of the second preliminary insulating layer through a dry etching process. In addition, while the removing of the portion of the first preliminary insulating layer and the portion of the second preliminary insulating layer is in progress, a portion of the second preliminary insulating layer overlapping the semi-transmitting area of the mask in a plan view may not be removed. For example, while the portion of the first preliminary insulating layer and the portion of the second preliminary insulating layer are removed by a dry etching process, the active pattern may not be etched.

Accordingly, in an embodiment, a thickness of the active pattern may not be reduced. Accordingly, a phenomenon in which a contact resistance between the active pattern and the contact electrode is increased and thus an amount of current flowing in the active pattern decreases may be prevented. In addition, as described above, while the removing of the portion of the first preliminary insulating layer and the portion of the second preliminary insulating layer through a dry etching process, the active pattern is not etched. Accordingly, Particles of the active pattern may be prevented from being attached to a portion of the photoresist pattern. Accordingly, a profile of the third side surface of the third hole may be uniform.

### BRIEF DESCRIPTION OF THE DRAWINGS

Illustrative, non-limiting embodiments will be more clearly understood from the following detailed description in conjunction with the accompanying drawings.

FIG. 1 is a plan view illustrating a display device, according to an embodiment.

FIG. 2 is a cross-sectional view of the display device of FIG. 1 taken along line I-I′, according to an embodiment.

FIG. 3 is an enlarged cross-sectional view of the X area of FIG. 2, according to an embodiment.

FIG. 4A is an enlarged cross-sectional view of the Y area of FIG. 3, according to an embodiment.

FIG. 4B is an enlarged cross-sectional view of the Y area of FIG. 3, according to an embodiment.

FIG. 5 is a cross-sectional view illustrating a method of manufacturing the display device of FIG. 2, according to an embodiment.

FIG. 6 is a cross-sectional view illustrating a method of manufacturing the display device of FIG. 2, according to an embodiment.

FIG. 7 is a cross-sectional view illustrating a method of manufacturing the display device of FIG. 2, according to an embodiment.

FIG. 8 is a cross-sectional view illustrating a method of manufacturing the display device of FIG. 2, according to an embodiment.

FIG. 9 is a cross-sectional view illustrating a method of manufacturing the display device of FIG. 2, according to an embodiment.

FIG. 10 is a cross-sectional view illustrating a method of manufacturing the display device of FIG. 2, according to an embodiment.

FIG. 11 is a cross-sectional view illustrating a method of manufacturing the display device of FIG. 2, according to an embodiment.

FIG. 12 is a cross-sectional view illustrating a method of manufacturing the display device of FIG. 2, according to an embodiment.

FIG. 13 is a block diagram illustrating an electronic device, according to an embodiment.

FIG. 14 is a schematic diagram of an electronic device, according to various embodiments.

### DETAILED DESCRIPTION

Hereinafter, display devices, in accordance with embodiments, will be described in more detail with reference to the accompanying drawings. The same reference numerals are used for the same components in the drawings, and redundant descriptions of the same components will be omitted.

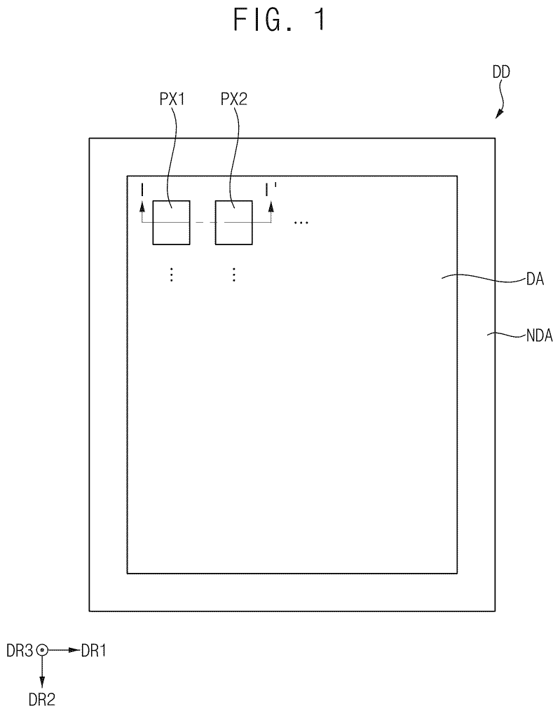

FIG. 1 is a plan view illustrating a display device, according to an embodiment.

In an embodiment and referring to FIG. 1, the display device DD may include a display area DA and a non-display area NDA.

In an embodiment, the display area DA may be an area that generates light or adjusts transmissivity of light provided from an external light source to display an image. A plurality of pixel areas may be located in the display area DA. For example, a first pixel area PX1 and a second pixel area PX2 may be located in the display area DA. Each of the plurality of pixel areas may emit light. For example, the first pixel area PX1 may emit a first light, and the second pixel area PX2 may emit a second light. In an embodiment, the first light may be red light, and the second light may be blue light, but the invention is not limited thereto.

In an embodiment, the plurality of pixel areas may be located over the entire display area DA. Accordingly, the display area DA may display an image. In an embodiment, the plurality of pixel areas may be repeatedly arranged along a first direction DR1 and a second direction DR2 crossing the first direction DR1. For example, the second pixel area PX2 may be spaced apart from the first pixel area PX1 in the first direction DR1.

In an embodiment, the non-display area NDA may surround at least a portion of the display area DA. A driver may be located in the non-display area NDA. The driver may provide a signal or a voltage to the plurality of pixel areas. For example, the driver may include a data driver, a gate driver, and/or the like. The non-display area NDA may not display an image.

In an embodiment, the first direction DR1 and the second direction DR2 crossing the first direction DR1 may be defined. For example, the second direction DR2 may be substantially directed perpendicular to the first direction DR1. However, the invention is not limited thereto, and the second direction DR2 may form an acute angle or an obtuse angle with the first direction DR1. In addition, a third direction DR3 crossing a plane formed by the first direction DR1 and the second direction DR2 may be defined. For example, the third direction DR3 may be substantially directed perpendicular to the plane formed by the first direction DR1 and the second directions DR2. However, the invention is not limited thereto, and the third direction DR3 may form an acute angle or an obtuse angle with the plane formed by the first direction DR1 and the second direction DR2.

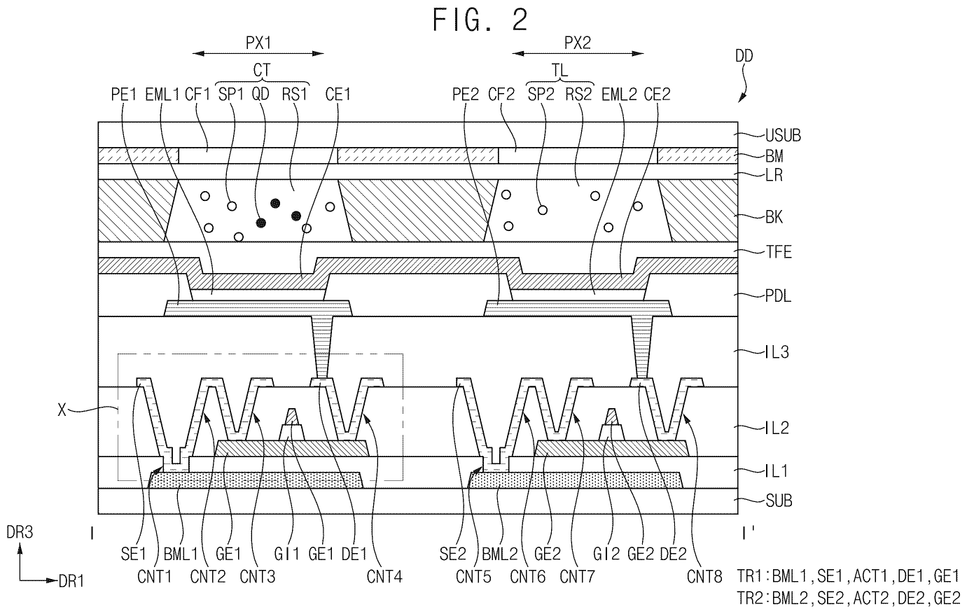

FIG. 2 is a cross-sectional view of the display device of FIG. 1 taken along line I-I′, according to an embodiment.

In an embodiment and referring to FIG. 2, the display device DD may include a substrate SUB, a first transistor TR1, a second transistor TR2, a first insulating layer IL1, a second insulating layer IL2, a third insulating layer IL3, a first gate insulating layer GI1, a second gate insulating layer GI2, a first pixel electrode PE1, a first light emitting layer EML1, a first common electrode CE1, a second pixel electrode PE2, a second light emitting layer EML2, a second common electrode CE2, a pixel defining layer PDL, an encapsulation layer TFE, a bank layer BK, a color conversion layer CT, a transmitting layer TL, a low refractive index layer LR, a black matrix layer BM, a first color filter CF1, a second color filter CF2, and an upper substrate USUB.

In an embodiment, the first transistor TR1 may include a first lower metal pattern BML1, a first contact electrode SE1, a first active pattern ACT1, a second contact electrode DE1, and a first gate electrode GE1. The second transistor TR2 may include a second lower metal pattern BML2, a third contact electrode SE2, a second active pattern ACT2, a fourth contact electrode DE2, and a second gate electrode GE2.

In an embodiment, the substrate SUB may include a transparent material or an opaque material and may be formed of a transparent resin substrate. Example of the transparent resin substrate may include a polyimide substrate. In this case, the polyimide substrate may include a first organic layer, a first barrier layer, a second organic layer, and/or the like. Optionally, in another embodiment, the substrate SUB may include a quartz substrate (e.g. a synthetic quartz substrate, a fluorine-doped quartz substrate), a calcium fluoride substrate, a sodalime glass substrate, a non-alkali glass substrate, and/or the like. These materials may be used alone or in combination with each other.

In an embodiment, the first lower metal pattern BML1 and the second lower metal pattern BML2 may be located on the substrate SUB. The second lower metal pattern BML2 may be spaced apart from the first lower metal pattern BML1 in a plan view. For example, as illustrated in FIG. 2, the second lower metal pattern BML2 may be spaced apart from the first lower metal pattern BML1 in the first direction DR1.

For example, in an embodiment, each of the first lower metal pattern BML1 and the second lower metal pattern BML2 may include a metal, an alloy, a metal nitride, a conductive metal oxide, a transparent conductive material, and/or the like. These materials may be used alone or in combination with each other. Examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), and/or the like. These materials may be used alone or in combination with each other. Examples of the conductive metal oxide may include Indium tin oxide, indium zinc oxide, and/or the like. These materials may be used alone or in combination with each other. In addition, examples of the metal nitride may include aluminum nitride (“AlNₓ”), tungsten nitride (“WNₓ”), chromium nitride (“CrNₓ”), and/or the like. These materials may be used alone or in combination with each other.

In an embodiment, the first insulating layer IL1 may be located on the substrate SUB and may cover the first lower metal pattern BML1 and the second lower metal pattern BML2. The first insulating layer IL1 may prevent metal atoms or impurities from being diffused from the substrate SUB to the first transistor TR1 and the second transistor TR2. In addition, when a surface of the substrate SUB is not uniform, the first insulating layer IL1 may improve flatness of the surface of the substrate SUB.

In an embodiment, the first insulating layer IL1 may include inorganic materials such as silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), and/or the like. These materials may be used alone or in combination with each other.

In an embodiment, the first active pattern ACT1 and the second active pattern ACT2 may be located on the first insulating layer IL1, where the second active pattern ACT2 may be spaced apart from the first active pattern ACT1 in the plan view. For example, as illustrated in FIG. 2, the second active pattern ACT2 may be spaced apart from the first active pattern ACT1 in the first direction DR1. Each of the first active pattern ACT1 and the second active pattern ACT2 may include a source area, a drain area, and a channel area located between the source area and the drain area.

For example, in an embodiment, each of the first active pattern ACT1 and the second active pattern ACT2 may include an inorganic semiconductor (e.g., amorphous silicon, polysilicon, a metal oxide semiconductor,), an organic semiconductor, and/or the like. These materials may be used alone or in combination with each other.

In an embodiment, the metal oxide semiconductor may include a binary compound (“ABₓ”), a ternary compound (“ABₓC_{y}”), a quaternary compound (“ABₓC_{y}D_{z}”), and/or the like including indium (“In”), zinc (“Zn”), gallium (“Ga”), tin (“Sn”), titanium (“Ti”), aluminum (“Al”), hafnium (“Hf”), zirconium (“Zr”), magnesium (“Mg”), and/or the like. These materials may be used alone or in combination with each other.

For example, in an embodiment, the metal oxide semiconductor may include zinc oxide (“ZnOₓ”), gallium oxide (“GaOₓ”), tin oxide (“SnOₓ”), indium oxide (“InOₓ”), indium gallium oxide (“IGO”), indium zinc oxide (“IZO”), indium tin oxide (“ITO”), indium zinc tin oxide (“IZTO”), and indium gallium zinc oxide (“IGZO”). These materials may be used alone or in combination with each other.

In an embodiment, the first gate insulating layer GI1 may be located on the first active pattern ACT1 and may at least partially overlap the first active pattern ACT1 in the plan view. For example, the first gate insulating layer GI1 may at least partially overlap the channel area of the first active pattern ACT1 in the plan view. The second gate insulating layer GI2 may be located on the second active pattern ACT2. The second gate insulating layer GI2 may at least partially overlap the second active pattern ACT2 in the plan view. For example, the second gate insulating layer GI2 may at least partially overlap the channel area of the second active pattern ACT2 in the plan view.

For example, in an embodiment, each of the first gate insulating layer GI1 and the second gate insulating layer GI2 may include inorganic materials such as silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), and/or the like. These materials may be used alone or in combination with each other.

In an embodiment, the first gate electrode GE1 may be located on the first gate insulating layer GI1 and may at least partially overlap the first gate insulating layer GI1 in the plan view. The second gate electrode GE2 may be located on the second gate insulating layer GI2. The second gate electrode GE2 may at least partially overlap the second gate insulating layer GI2 in the plan view.

In an embodiment, each of the first gate electrode GE1 and the second gate electrode GE2 may include a metal, an alloy, a metal nitride, a conductive metal oxide, a transparent conductive material, and/or the like. These materials may be used alone or in combination with each other. Examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), and/or the like. These materials may be used alone or in combination with each other. Examples of the conductive metal oxide may include Indium tin oxide, indium zinc oxide, and/or the like. These materials may be used alone or in combination with each other. In addition, examples of the metal nitride may include aluminum nitride (“AlNₓ”), tungsten nitride (“WNₓ”), chromium nitride (“CrNₓ”), and/or the like. These materials may be used alone or in combination with each other.

In an embodiment, the second insulating layer IL2 may be located on the first insulating layer IL1 and may cover at least a portion of each of the first active pattern ACT1, the first gate insulating layer GI1, the first gate electrode GE1, the second active pattern ACT2, the second gate insulating layer GI2 and the second gate electrode GE2.

For example, in an embodiment, the second insulating layer IL2 may include inorganic materials such as silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), and/or the like. These materials may be used alone or in combination with each other.

In an embodiment, the first contact electrode SE1, the second contact electrode DE1, the third contact electrode SE2 and the fourth contact electrode DE2 may be located on the second insulating layer IL2. The first contact electrode SE1, the second contact electrode DE1, the third contact electrode SE2 and the fourth contact electrode DE2 may be spaced apart from each other in a plan view. For example, as illustrated in FIG. 2, the second contact electrode DE1 may be spaced apart from the first contact electrode SE1 in the first direction DR1, the third contact electrode SE2 may be spaced apart from the second contact electrode DE1 in the first direction DR1, and the fourth contact electrode DE2 may be spaced apart from the third contact electrode SE2 in the first direction DR1.

For example, in an embodiment, each of the first contact electrode SE1, the second contact electrode DE1, the third contact electrode SE2 and the fourth contact electrode DE2 may include a metal, an alloy, a metal nitride, a conductive metal oxide, a transparent conductive material, and/or the like. Examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), and/or the like. These materials may be used alone or in combination with each other. Examples of the conductive metal oxide may include Indium tin oxide, indium zinc oxide, and/or the like. These materials may be used alone or in combination with each other. In addition, examples of the metal nitride may include aluminum nitride (“AlNₓ”), tungsten nitride (“WNₓ”), chromium nitride (“CrNₓ”), and/or the like. These materials may be used alone or in combination with each other.

In an embodiment, the third insulating layer IL3 may be located on the second insulating layer IL2 and may cover the first contact electrode SE1, the second contact electrode DE1, the third contact electrode SE2 and the fourth contact electrode DE2.

In an embodiment, the third insulating layer IL3 may include an organic material. For example, the third insulating layer IL3 may include phenolic resin, acrylic resin, polyimide resin, polyamide resin, siloxane resin, epoxy resin, and/or the like. These materials may be used alone or in combination with each other. However, the invention is not limited thereto, and in another embodiment, the third insulating layer IL3 may further include an inorganic material.

In an embodiment, the first pixel electrode PE1 and the second pixel electrode PE2 may be located on the third insulating layer IL3. The first pixel electrode PE1 may be located in the first pixel area PX1. The first pixel electrode PE1 may contact the second contact electrode DE1 through a first contact hole penetrating (or, defining through) the third insulating layer IL3. For example, the first pixel electrode PE1 may operate as an anode of a first light emitting element. The first light emitting element may include a first pixel electrode PE1, a first light emitting layer EML1, and a first common electrode CE1. The second pixel electrode PE2 may be located in the second pixel area PX2. The second pixel electrode PE2 may contact the fourth contact electrode DE2 through a second contact hole penetrating (or, defining through) the third insulating layer IL3. For example, the second pixel electrode PE2 may operate as an anode of a second light emitting element. The second light emitting element may include a second pixel electrode PE2, a second light emitting layer EML2, and a second common electrode CE2.

For example, in an embodiment, each of the first pixel electrode PE1 and the second pixel electrode PE2 may have a stacked structure including ITO/Ag/ITO, but this disclosure is not limited thereto.

In an embodiment, the pixel defining layer PDL may be located on the third insulating layer IL3 and may cover a side portion of the first pixel electrode PE1. For example, in the pixel defining layer PDL, a first opening exposing a portion of an upper surface of the first pixel electrode PE1 may be defined. In addition, the pixel defining layer PDL may cover a side portion of the second pixel electrode PE2. For example, in the pixel defining layer PDL, a second opening exposing a portion of an upper surface of the second pixel electrode PE2 may be defined.

For example, in an embodiment, the pixel defining layer PDL may include an inorganic material or an organic material. In an embodiment, the pixel defining layer PDL may include an organic material such as an epoxy resin, a siloxane resin, and/or the like. These materials may be used alone or in combination with each other. In another embodiment, the pixel defining layer PDL may further include a light blocking material including a black pigment, a black dye, and/or the like.

In an embodiment, the first light emitting layer EML1 may be located on the first pixel electrode PE1. The first light emitting layer EML1 may be located in the first pixel area PX1. The first light emitting layer EML1 may include an organic material that emits the first light. The second light emitting layer EML2 may be located in the second pixel area PX2. The second light emitting layer EML2 may include an organic material that emits the second light.

In an embodiment, the first common electrode CE1 may be located on the first light emitting layer EML1. The first common electrode CE1 may be located in the first pixel area PX1. For example, the first common electrode CE1 may operate as a cathode of the first light emitting element. The second common electrode CE2 may be located on the second light emitting layer EML2. The second common electrode CE2 may be located in the second pixel area PX2. For example, the second common electrode CE2 may operate as a cathode of the second light emitting element. In an embodiment, the first common electrode CE1 and the second common electrode CE2 may be connected to each other. For example, the first common electrode CE1 and the second common electrode CE2 may be integrally formed. However, the invention is not limited thereto, and in another embodiment, the first common electrode CE1 and the second common electrode CE2 may be separated from each other.

For example, in an embodiment, each of the first common electrode CE1 and the second common electrode CE2 may include a metal, an alloy, a metal nitride, a conductive metal oxide, a transparent conductive material, and/or the like. These materials may be used alone or in combination with each other.

In an embodiment, the encapsulation layer TFE may be located on the first common electrode CE1 and the second common electrode CE2. The encapsulation layer TFE may prevent impurities, moisture, and/or the like from penetrating into the first light emitting element and the second light emitting element from an outside.

For example, in an embodiment, the encapsulation layer TFE may include at least one inorganic encapsulation layer and at least one organic encapsulation layer. For example, the inorganic encapsulation layer and the organic encapsulation layer may be alternately stacked. For example, the one inorganic encapsulation layer may include silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), and/or the like. These materials may be used alone or in combination with each other. The organic encapsulation layer may include a cured polymer such as polyacrylate.

In an embodiment, the bank layer BK may be located on the encapsulation layer TFE, where the bank layer BK may define a first opening in the first pixel area PX1. The color conversion layer CT to be described later may be located in the first opening of the bank layer BK. In addition, the bank layer BK may define a second opening in the second pixel area PX2. The transmitting layer TL to be described later may be located in the second opening of the bank layer BK. The bank layer BK may prevent color mixing between adjacent pixel areas. For example, the bank layer BK may prevent color mixing between the first pixel area PX1 and the second pixel area PX2.

For example, in an embodiment, the bank layer BK may include an organic material. In an embodiment, the bank layer BK may include a light blocking material. For example, the bank layer BK may include a black pigment, a black dye, carbon black, and/or the like. These materials may be used alone or in combination with each other.

In an embodiment, the color conversion layer CT may be located in the first opening of the bank layer BK. For example, the color conversion layer CT may be located in the first pixel area PX1. The color conversion layer CT may include a first resin portion RS1, a first scattering body SP1, and a wavelength conversion particle QD.

For example, in an embodiment, the first resin portion RS1 may include an epoxy resin, an acrylic resin, a phenol resin, a melamine resin, a cardo resin, an imide resin, and/or the like, but the invention is not limited thereto. These materials may be used alone or in combination with each other.

In an embodiment, the first scattering body SP1 may scatter a first incident light incident on the color conversion layer CT from the first light emitting element to increase an optical path without substantially converting a wavelength of the first incident light. In an embodiment, the first scattering body SP1 may include a metal oxide or an organic material. In an embodiment, the first scattering body SP1 may include titanium dioxide (“TiO₂”).

In an embodiment, the wavelength conversion particle QD may emit light by stimulation by light. The wavelength conversion particle QD may include an II-VI group semiconductor compound, an III-VI group semiconductor compound, an III-V group semiconductor compound, an IV-VI group semiconductor compound, an IV group element or a compound including the IV group element, an I-III-VI group semiconductor compound, and/or the like. These materials may be used alone or in combination with each other.

In an embodiment, the II-VI group semiconductor compound may include a binary compound such as CdS, CdSe, CdTe, ZnS, ZnSe, ZnTe, ZnO, HgS, HgSe, HgTe, MgS, MgSe, and/or the like; a ternary compound such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe MgZnS, MgZnSe, and/or the like; a quaternary compounds such as CdZnSeS, CdZnSeTe, CdZnSTe, CdHgSeS, CdHgSeTe, CdHgSTe, HgZnSeS, HgZnSeTe, HgZnSTe, and/or the like; and any combination of the above compounds.

In an embodiment, the III-VI group semiconductor compound may include a binary compound such as In₂S₃, Ga₂S₃, and/or the like, a ternary compound such as InGaS₃, InGaSe₃ and/or the like and or any combination of the above compounds.

In an embodiment, the III-V group semiconductor compound may include a binary compound such as GaN, GaP, GaAs, GaSb, AlN, AlP, AlAs, AlSb, InN, InP, InAs, InSb, and/or the like, a ternary compound such as GaNP, GaNAs, GaNSb, GaPAs, GaPSb, AlNP, AlNAs, AlNSb, AlPAs, AlPSb, InAsP, InGaP, InGaAs, InAlP, InNP, InNAs, InNSb, InPAs, InPSb, GaAlNP, and/or the like, a quaternary compound such as GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and/or the like and any combination of the above compounds.

In an embodiment, the IV-VI group semiconductor compound may include a binary compound such as SnS, SnSe, SnTe, PbS, PbSe, PbTe, and/or the like, a ternary compound such as SnSeS, SnSeTe, SnSTe, PbSeS, PbSeTe, PbSTe, SnPbS, SnPbSe, SnPbTe, and/or the like, a quaternary compound such as SnPbSSe, SnPbSeTe, SnPbSTe, and/or the like and any combination of the above compounds.

In an embodiment, the IV group element and the compound including the IV group element may include a binary compound such as Si and/or Ge, a binary compound such as SiC, SiGe, and/or the like and any combination of the above compounds.

In an embodiment, the I-III-VI group semiconductor compound may include a ternary compound such as AgInS, AgInS₂, CuInS, CuInS₂, CuGaO₂, AgGaO₂, AgAlO₂, and/or the like and any combination of the above compounds. The I-III-VI group semiconductor compound may further include an II group element. For example, the I-III-VI group semiconductor compound may include a quaternary compound such as CuInZnS.

In an embodiment, the transmitting layer TL may be located in the second opening of the bank layer BK. For example, the transmitting layer TL may be located in the second pixel area PX2. The transmitting layer TL may include a second resin portion RS2 and a second scattering body SP2.

For example, in an embodiment, the second resin portion RS2 may include an epoxy resin, an acrylic resin, a phenol resin, a melamine resin, a cardo resin, an imide resin, and/or the like, but the invention is not limited thereto. These materials may be used alone or in combination with each other.

In an embodiment, the second scattering body SP2 may scatter a second incident light incident on the transmitting layer TL from the second light emitting element to increase an optical path without substantially converting a wavelength of the second incident light. In an embodiment, the second scattering body SP2 may include a metal oxide or an organic material. In an embodiment, the second scattering body SP2 may include titanium dioxide (“TiO₂”).

In an embodiment, the low refractive index layer LR may be located on the bank layer BK. The low refractive index layer LR may increase light extraction efficiency, thereby increasing luminance and lifetime of the display device DD. For example, the low refractive index layer LR may include an organic material.

In an embodiment, the black matrix layer BM may be located on the low refractive index layer LR. The black matrix layer BM may define a first opening in the first pixel area PX1. The first color filter CF1 to be described later may be located in the first opening of the black matrix layer BM. In addition, the black matrix layer BM2 may define a second opening in the second pixel area PX2. The second color filter CF2 to be described later may be located in the second opening of the black matrix layer BM2.

In an embodiment, the black matrix layer BM may include a black resin-based material that absorbs light, but the invention is not limited thereto. For example, the black matrix layer BM may include an opaque metal such as chromium (“Cr”) or chromium oxide (“CrOₓ”).

In an embodiment, the upper substrate USUB may be located on the black matrix layer BM. Examples of materials that may be used as the upper substrate USUB may include glass, plastic, and/or the like.

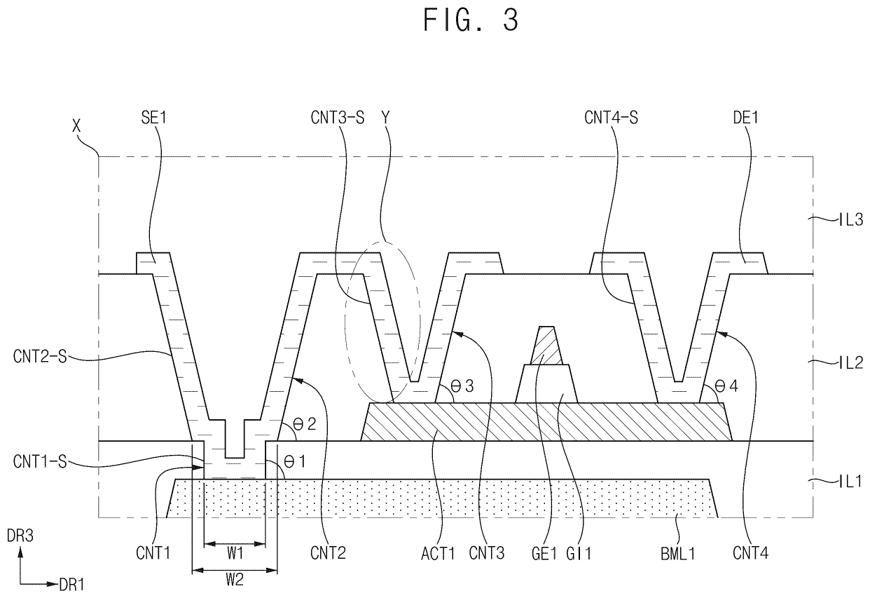

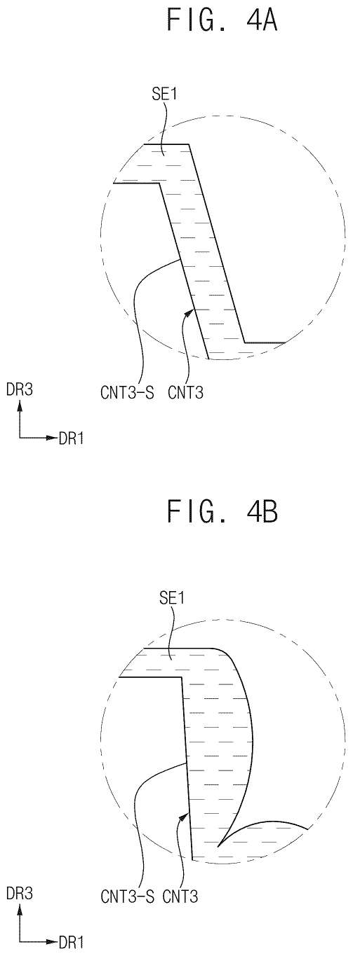

FIG. 3 is an enlarged cross-sectional view of the X area of FIG. 2, according to an embodiment. FIG. 4A is an enlarged cross-sectional view of the Y area of FIG. 3, according to an embodiment. FIG. 4B is an enlarged cross-sectional view of the Y area of FIG. 3, according to an embodiment. Specifically, FIG. 4A is a cross-sectional view illustrating the Y area when a third angle θ3 is less than about 70 degrees, according to an embodiment, and FIG. 4B is a cross-sectional view illustrating the Y area when the third angle θ3 exceeds about 70 degrees, according to an embodiment.

In an embodiment and referring to FIGS. 2 and 3, the first insulating layer IL1 may define a first hole CNT1, where the first hole CNT1 may be a portion obtained by removing at least a portion of the first insulating layer IL1. For example, the first hole CNT1 may be a portion obtained by removing the first insulating layer IL1 from an upper surface of the first insulating layer IL1 to an upper surface of the first lower metal pattern BML1. The first hole CNT1 may include a side surface CNT1-S. The side surface CNT1-S of the first hole CNT1 may form a first angle θ1 with the upper surface of the first lower metal pattern BML1. In an embodiment, the first angle θ1 may be about 90 degrees, but the invention is not limited thereto, and the first angle θ1 may have a value less than about 90 degrees.

In an embodiment, the second insulating layer IL2 may define a second hole CNT2, where the second hole CNT2 may be a portion obtained by removing at least a portion of the second insulating layer IL2. For example, the second hole CNT2 may be a portion obtained by removing the second insulating layer IL2 from an upper surface of the second insulating layer IL2 to an upper surface of the first insulating layer IL1. The second hole CNT2 may at least partially overlap the first hole CNT1 in a plan view. The second hole CNT2 may be spatially connected to the first hole CNT1 to form one contact hole. A portion of the upper surface of the first lower metal pattern BML1 may be exposed through the contact hole. In an embodiment, the second hole CNT2 may have an inverted trapezoidal shape in a cross-sectional view. For example, the second hole CNT2 may have an inverted trapezoidal shape in which a width W2 of a lower surface is smaller than a width of an upper surface in the cross-sectional view. In the present specification, a width may mean a width in the first direction DR1. In an embodiment, the width W2 of the lower surface of the second hole CNT2 may be greater than a width W1 of the first hole CNT1. When a value of the width W1 of the first hole CNT1 is not determined as one (i.e., when a value of the width of the first hole CNT1 increases in the third direction DR3 or when the value of the width of the first hole CNT1 decreases in the third direction DR3), the width W2 of the lower surface of the second hole CNT2 may be greater than a largest width of the first hole CNT1. The second hole CNT2 may include a side surface CNT2-S. In an embodiment, the side surface CNT2-S of the second hole CNT2 may be spaced apart from the side surface CNT1-S of the first hole CNT1. In this case, a portion of the upper surface of the first insulating layer IL1 may connect the side surface CNT2-S of the second hole CNT2 to the side surface CNT1-S of the first hole CNT1. The side surface CNT2-S of the second hole CNT2 may form a second angle θ2 with the upper surface of the first insulating layer IL1. In an embodiment, the second angle θ2 may be less than the first angle θ1. For example, the second angle θ2 may be equal to or less than about 70 degrees. For example, the second angle θ2 may be equal to or greater than about 0 degrees and equal to or less than about 70 degrees. For example, the second angle θ2 may be equal to or greater than about 35 degrees and equal to or less than about 55 degrees.

In an embodiment, the second insulating layer IL2 may define a third hole CNT3, where the third hole CNT3 may be a portion obtained by removing a portion of the second insulating layer IL2. For example, the third hole CNT3 may be a portion obtained by removing the second insulating layer IL2 from an upper surface of the second insulating layer IL2 to an upper surface of the first active pattern ACT1. The third hole CNT3 may be spaced apart from the first hole CNT1 and the second hole CNT2 in a plan view. A portion of the upper surface of the first active pattern ACT1 may be exposed through the third hole CNT3. In an embodiment, the third hole CNT3 may have an inverted trapezoidal shape in the cross-sectional view. For example, the third hole CNT3 may have an inverted trapezoidal shape in which a width of a lower surface is smaller than a width of an upper surface in the cross-sectional view. The third hole CNT3 may include a side surface CNT3-S. The side surface CNT3-S of the third hole CNT3 may form a third angle θ3 with the upper surface of the first active pattern ACT1. In an embodiment, the third angle θ3 may be less than the first angle θ1. For example, the third angle θ3 may be equal to or less than about 70 degrees. For example, the third angle θ3 may be equal to or greater than about 0 degrees and equal to or less than about 70 degrees. For example, the third angle θ3 may be equal to or greater than about 35 degrees and equal to or less than about 55 degrees. In an embodiment, the second angle θ2 and the third angle θ3 may have substantially a same value.

In an embodiment, the second insulating layer IL2 may define a fourth hole CNT4, where the fourth hole CNT4 may be a portion obtained by removing a portion of the second insulating layer IL2. For example, the fourth hole CNT4 may be a portion obtained by removing the second insulating layer IL2 from an upper surface of the second insulating layer IL2 to an upper surface of the first active pattern ACT1. The fourth hole CNT4 may be spaced apart from the second hole CNT2 and the third hole CNT3 in the plan view. A portion of the upper surface of the first active pattern ACT1 may be exposed through the fourth hole CNT4. In an embodiment, the fourth hole CNT4 may have an inverted trapezoidal shape in the cross-sectional view. For example, the fourth hole CNT4 may have an inverted trapezoidal shape in which a width of a lower surface is less than a width of an upper surface in the cross-sectional view. The fourth hole CNT4 may include a side surface CNT4-S. The side surface CNT4-S of the fourth hole CNT4 may form a fourth angle θ4 with the upper surface of the first active pattern ACT1. In an embodiment, the fourth angle θ4 may be smaller than the first angle θ1. For example, the fourth angle θ4 may be equal to or less than about 70 degrees. For example, the fourth angle θ4 may be equal to or greater than about 0 degrees and equal to or less than about 70 degrees. For example, the fourth angle θ4 may be equal to or greater than about 35 degrees and equal to or less than about 55 degrees. In an embodiment, the fourth angle θ4 and the third angle θ3 may have substantially a same value. In an embodiment, the fourth angle θ4 and the second angle θ2 may have substantially a same value.

In an embodiment, the first contact electrode SE1 may contact the first lower metal pattern BML1 through the first hole CNT1 and the second hole CNT2. For example, as the first contact electrode SE1 is extended from the upper surface of the second insulating layer IL2 along the side surface CNT1-S of the first hole CNT1 and the side surface CNT2-S of the second hole CNT2, the first contact electrode SE1 may contact the upper surface of first lower metal pattern BML1. The first contact electrode SE1 may contact the first active pattern ACT1 through the third hole CNT3. For example, as the first contact electrode SE1 is extended from the upper surface of the second insulating layer IL2 along the side surface CNT3-S of the third hole CNT3, the first contact electrode SE1 may contact the upper surface of the first active pattern ACT1. For example, the first contact electrode SE1 may be referred to as a first electrode. The second contact electrode DE1 may contact the first active pattern ACT1 through the fourth hole CNT4. For example, as the second contact electrode DE1 extends along the side surface CNT4-S of the fourth hole CNT4 from the upper surface of the second insulating layer IL2, the second contact electrode DE1 may contact the upper surface of the first active pattern ACT1. For example, the second contact electrode DE1 may be referred to as a second electrode.

In an embodiment and referring further to FIG. 4A, as described above, the second angle θ2 may be equal to or less than about 70 degrees. Accordingly, a thickness of the first contact electrode SE1 located along the side surface CNT2-S of the second hole CNT2 may be constant in the second hole CNT2. In addition, a thickness of an insulating layer (e.g., the third insulating layer IL3, and/or the like) stacked on the first contact electrode SE1 in the second hole CNT2 may be constant in the second hole CNT2.

In an embodiment, the third angle θ3 may be equal to or less than about 70 degrees. Accordingly, as illustrated in FIG. 4A, a thickness of the first contact electrode SE1 located along the side surface CNT3-S of the third hole CNT3 may be constant in the third hole CNT3. In addition, a thickness of an insulating layer (e.g., the third insulating layer IL3, and/or the like) stacked on the first contact electrode SE1 in the third hole CNT3 may be constant in the third hole CNT3.

In an embodiment and referring further to FIG. 4B, when the third angle θ3 exceeds about 70 degrees, a thickness of the first contact electrode SE1 located along the side surface CNT3-S of the third hole CNT3 may not be constant in the third hole CNT3. In addition, a thickness of an insulating layer (e.g., the third insulating layer IL3, and/or the like) stacked on the first contact electrode SE1 in the third hole CNT3 may not be constant in the third hole CNT3. For example, a thickness of the first contact electrode SE1 in a direction in which the first contact electrode SE1 contacts the side surface CNT3-S of the third hole CNT3 may not be constant. For example, as illustrated in FIG. 4B, the first contact electrode SE1 may include a portion having a relatively large thickness and a portion having a relatively small thickness in the third hole CNT3. In addition, the insulating layer located on the first contact electrode SE1 in the third hole CNT3 may include a portion having a relatively large thickness and a portion having a relatively small thickness. In this case, impurities such as moisture, oxygen, and/or the like may penetrate into the portion of the first contact electrode SE1 having a relatively small thickness. The impurities may penetrate into a portion of the first active pattern ACT1 (for example, the channel area of the first active pattern ACT1), and thus conductivity of the channel area of the first active pattern ACT1 may be increased. Accordingly, a bright spot defect in which a pixel area (for example, the first pixel area PX1) emits light regardless of a signal applied to the first active pattern ACT1 through the first contact electrode SE1 may occur. According to an embodiment, as the third angle θ3 is equal to or less than about 70 degrees, a thickness of the first contact electrode SE1 located along the side surface CNT3-S of the third hole CNT3 may be constant in the third hole CNT3. Accordingly, it is possible to prevent the bright spot defect from occurring in the pixel area.

In an embodiment, although an effect according to the third angle θ3 is equal to or less than about 70 degrees has been described with reference to FIG. 4A and FIG. 4B, this description may also be applied as an effect according to the fourth angle θ4 is equal to or less than about 70 degrees. Therefore, description of the effect according to the fourth angle θ4 is equal to or less than about 70 degrees will be omitted.

In addition, although structures of the first transistor TR1, the first insulating layer IL1 located around the first transistor TR1, the second insulating layer IL2, and the third insulating layer IL3 have been mainly described with reference to FIGS. 2, 3, 4A, and 4B, structures of the second transistor TR2, the first insulating layer IL1 located around the second transistor TR2, the second insulating layer IL2, and the third insulating layer IL3 may be substantially same as those described with reference to FIGS. 2, 3, 4A, and 4B. For example, in an embodiment, the fifth hole CNT5 and the first hole CNT1 may have substantially a same structure, the sixth hole CNT6 and the second hole CNT2 may have substantially a same structure, the seventh hole CNT7 and the third hole CNT3 may have substantially a same structure, and the eighth hole CNT8 and the fourth hole CNT4 may have substantially a same structure.

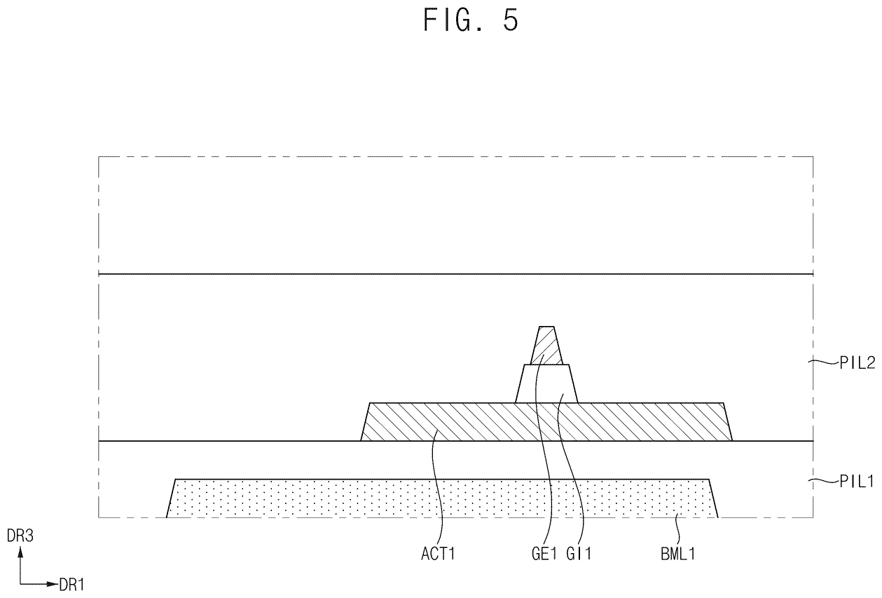

FIGS. 5, 6, 7, 8, 9, 10, 11, and 12 are cross-sectional views illustrating a method of manufacturing the display device of FIG. 2, according to an embodiment. Specifically, FIGS. 5, 6, 7, 8, 9, 10, 11, and 12 are cross-sectional views illustrating a method of manufacturing a portion corresponding to the X area of FIG. 2 of the display device.

In an embodiment and referring to FIG. 5, the first lower metal pattern BML1 may be formed on the substrate (for example, the substrate SUB of FIG. 2). In addition, a first preliminary insulating layer PIL1 may be formed on the substrate. The first preliminary insulating layer PIL1 may be formed to cover the first lower metal pattern BML1.

In an embodiment, the first preliminary insulating layer PIL1 may include inorganic materials such as silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), and/or the like. These materials may be used alone or in combination with each other.

In an embodiment, the first active pattern ACT1 may be formed on the first preliminary insulating layer PIL1. The first gate insulating layer GI1 may be formed on the first active pattern ACT1. The first gate insulating layer GI1 may be formed to at least partially overlap the first active pattern ACT1 in the plan view. The first gate electrode GE1 may be formed on the first gate insulating layer GI1. The first gate electrode GE1 may be formed to at least partially overlap the first gate insulating layer GI1 in the plan view.

In an embodiment, a second preliminary insulating layer PIL2 may be formed on the first preliminary insulating layer PIL1, where the second preliminary insulating layer PIL2 may be formed to cover at least a portion of each of the first active pattern ACT1, the first gate insulating layer GI1, and the first gate electrode GE1.

In an embodiment, the second preliminary insulating layer PIL2 may include silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), and/or the like. These materials may be used alone or in combination with each other.

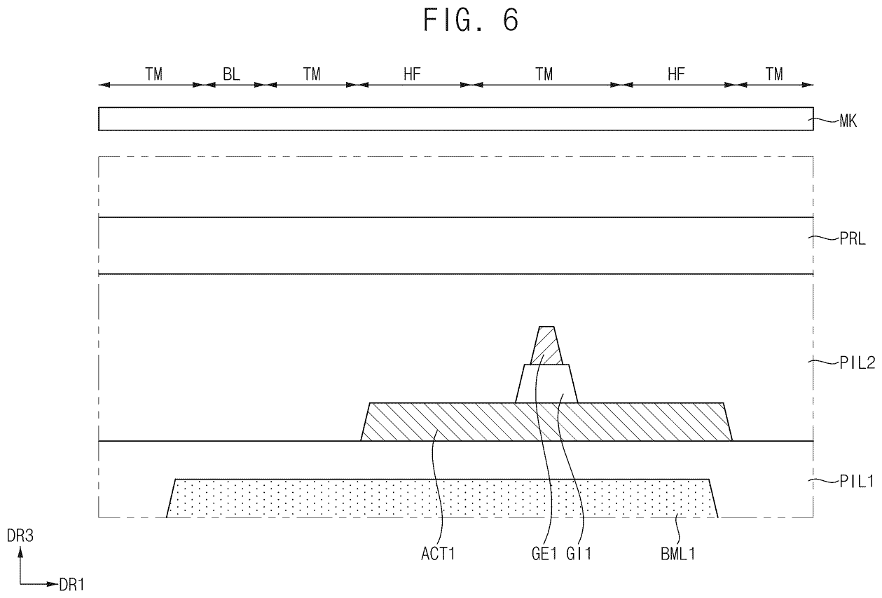

In an embodiment and referring to FIG. 6, a photoresist layer PRL may be formed on the second preliminary insulating layer PIL2. A mask MK may be placed on the photoresist layer PRL. The mask MK may include a transmitting area TM, a blocking area BL, and a semi-transmitting area HF.

In an embodiment, the transmitting area TM may be an area through which light is transmitted from the mask MK to the photoresist layer PRL. The blocking area BL may be an area in which light from the mask MK to the photoresist layer PRL is completely blocked. The semi-transmitting area HF may be an area through which light in an amount less than light passing through the transmitting area TM is transmitted from the mask MK to the photoresist layer PRL.

In an embodiment, the photoresist layer PRL may be a positive photoresist or a negative photoresist. Hereinafter, for convenience of description, a case where the photoresist layer PRL is a negative photoresist will be described.

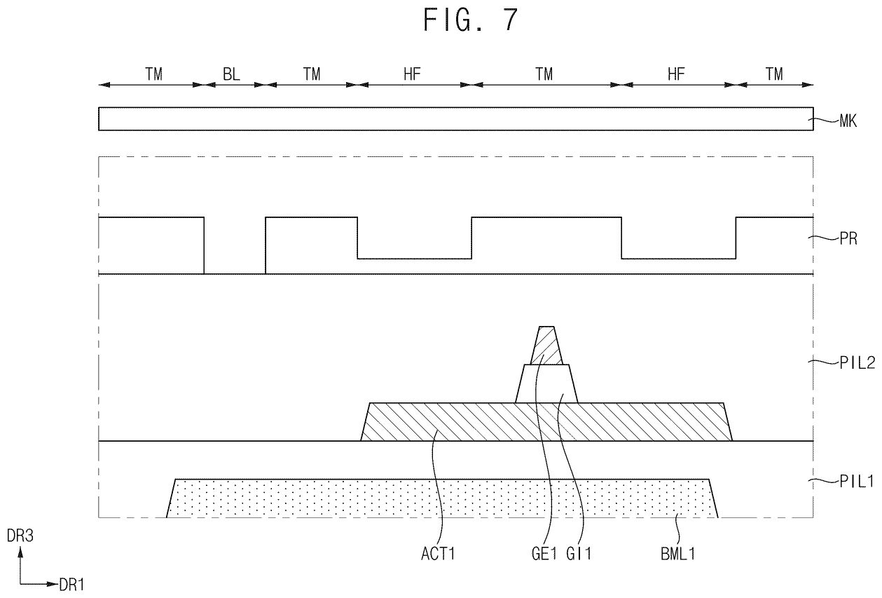

In an embodiment and referring further to FIG. 7, the photoresist layer PRL may be subjected to an exposure process and then a developing process. Accordingly, a photoresist pattern PR may be formed. For example, a portion of the photoresist layer PRL overlapping the blocking area BL in the plan view may be removed. A portion of the photoresist layer PRL overlapping the blocking area BL in the plan view may be completely removed. In addition, a portion of the photoresist layer PRL overlapping the semi-transmitting area HF in the plan view may be removed. Only a portion of the photoresist layer PRL overlapping the semi-transmitting area HF in the plan view may be removed. For example, a portion of the portion of the photoresist layer PRL overlapping the semi-transmitting area HF in the plan view may remain without being removed even after an exposure process and a developing process.

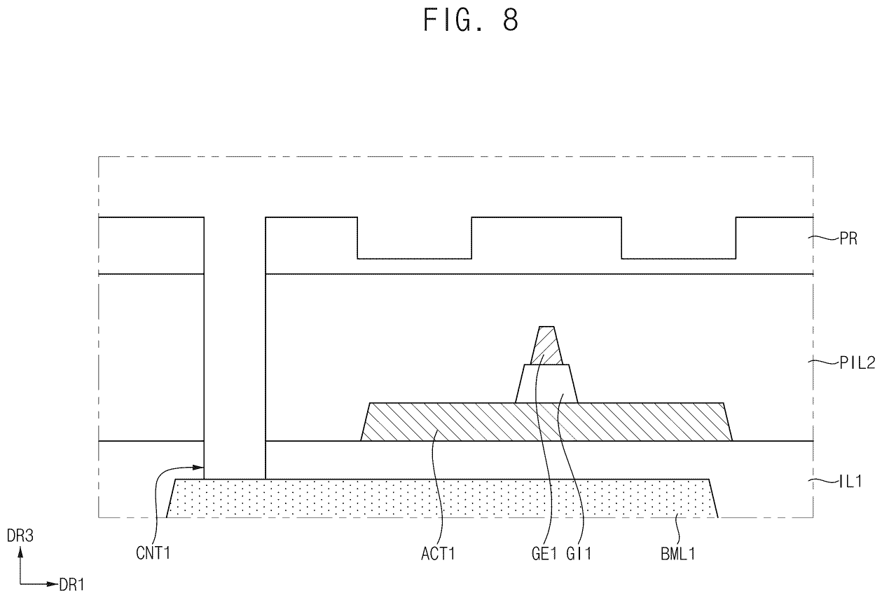

In an embodiment and referring to FIGS. 7 and 8, a portion of the first preliminary insulating layer PIL1 and a portion of the second preliminary insulating layer PIL2 may be removed through the photoresist pattern PR. The portion of the first preliminary insulating layer PIL1 may be removed to form the first insulating layer IL1 defining the first hole CNT1. In an embodiment, the portion of the first preliminary insulating layer PIL1 and the portion of the second preliminary insulating layer PIL2 may be removed by a dry etching process. For example, the portion of the first preliminary insulating layer PIL1 and the portion of the second preliminary insulating layer PIL2 may be removed by a dry etching process using gas including tetrafluoromethane (“CF₄”), argon (“Ar”), and oxygen (“O₂”). However, the invention is not limited thereto, and materials constituting gas for the dry etching process may be variously changed according to embodiments. The dry etching process for removing the portion of the first preliminary insulating layer PIL1 and the portion of the second preliminary insulating layer PIL2 may be an anisotropic etching process. As the portion of the first preliminary insulating layer PIL1 and the portion of the second preliminary insulating layer PIL2 are removed, at least a portion of the upper surface of the first lower metal pattern BML1 may be exposed.

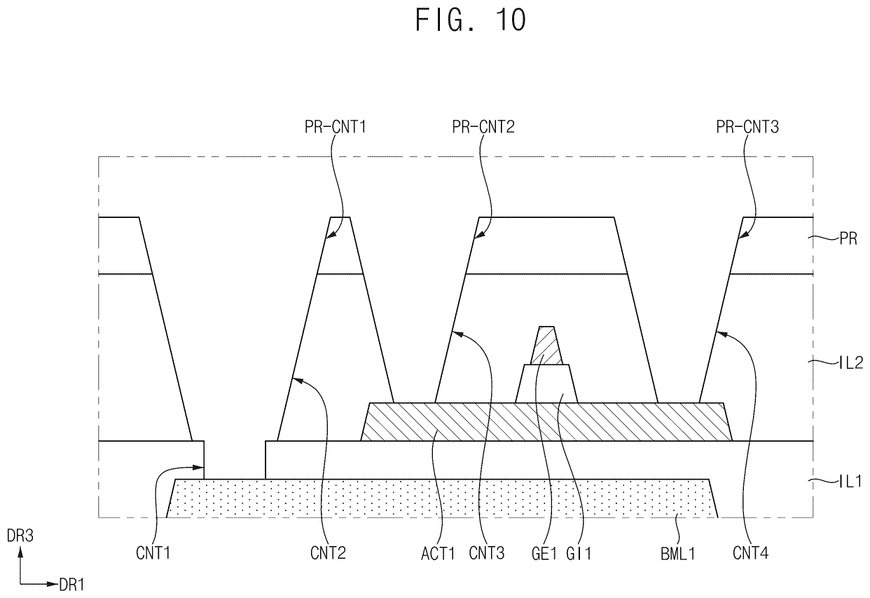

In an embodiment, while the portion of the first preliminary insulating layer PIL1 and the portion of the second preliminary insulating layer PIL2 are removed, a portion of the second preliminary insulating layer PIL2 overlapping the semi-transmitting area HF in the plan view may not be removed. This may be because a portion of the portion of the photoresist layer (e.g., the photoresist layer PR of FIG. 6) overlapping the semi-transmitting area HF in a plan view is not removed and remains even after undergoing an exposure process and a development process. Accordingly, after the upper surface of the first lower metal pattern BML1 is exposed, the upper surface of the first active pattern ACT1 may be exposed (see FIG. 10). For example, while the portion of the first preliminary insulating layer PIL1 and the portion of the second preliminary insulating layer PIL2 are removed through a dry etching process, the active pattern may not be etched.

In an embodiment, if the blocking area BL is located instead at a position of the semi-transmitting area HF of the mask MK, a dry etching process exposing the upper surface of the first lower metal pattern BML1 and a dry etching process exposing the upper surface of the first active pattern ACT1 may be performed simultaneously. In this case, a process of etching the first preliminary insulating layer PIL1 and the second preliminary insulating layer PIL2 may be continued so that the upper surface of the first lower metal pattern BML1 located below the first active pattern ACT1 may be exposed even after a time point when the upper surface of the first active pattern ACT1 is exposed. Therefore, while a process of etching the first preliminary insulating layer PIL1 and the second preliminary insulating layer PIL2 is continued so that the upper surface of the first lower metal pattern BML1 may be exposed, the first active pattern ACT1 may also be etched. Therefore, a thickness of the first active pattern ACT1 in the third direction DR3 may be reduced. When the thickness of the first active pattern ACT1 is reduced, contact resistance between the first contact electrode (e.g., the first contact electrode SE1 of FIG. 3) and the first active pattern ACT1 may increase. In addition, when the thickness of the first active pattern ACT1 is reduced, contact resistance between the second contact electrode (e.g., the second contact electrode DE1 of FIG. 3) and the first active pattern ACT1 may increase. Accordingly, even when a signal is applied to the first active pattern ACT1 through the first contact electrode and/or the second contact electrode, an amount of current flowing through the first active pattern ACT1 may be reduced. Accordingly, luminance of light emitted from the first pixel area (e.g., the first pixel area PX1 of FIG. 2) may be different from desired luminance. According to an embodiment, while the portion of the first preliminary insulating layer PIL1 and the portion of the second preliminary insulating layer PIL2 are removed, a portion of the second preliminary insulating layer PIL2 overlapping the semi-transmitting area HF in the plan view may not be removed. Accordingly, the first active pattern ACT1 may not be etched and the thickness of the first active pattern ACT1 may not be reduced. Accordingly, a phenomenon in which the contact resistance between the first active pattern ACT1 and the first contact electrode increases and thus an amount of current flowing through the first active pattern ACT1 decreases may be prevented. Accordingly, a phenomenon in which the luminance of light emitted from the first pixel area is different from the desired luminance may be prevented.

In addition, as described above, in an embodiment, if the blocking area BL is located instead at a position of the semi-transmitting area HF of the mask MK, the first active pattern ACT1 may also be etched while the process of etching the first preliminary insulating layer PIL1 and the second preliminary insulating layer PIL2 continues. In this process, particles of the first active pattern ACT1 may be attached to a portion of the photoresist pattern PR. For example, through an exposure process and a development process, an opening may be formed in a portion of the photoresist layer overlapping the blocking area BL located in place of the semi-transmitting area HF in the plan view, and the particles of the first active pattern ACT1 may be attached to a side surface of the opening. When a portion of the second preliminary insulating layer PIL2 is etched using the photoresist layer to which the particles are attached, a profile of the side surface (e.g., the side surface CNT3-S of FIG. 3) of the third hole (e.g., the third hole CNT3 of FIG. 3) exposing the first active pattern ACT1 and the side surface (e.g., the side surface CNT4-S of FIG. 3) of the fourth hole (e.g., the fourth hole CNT4 of FIG. 3) may not be uniform. In this case, impurities such as moisture, oxygen, and/or the like may penetrate through the side surfaces of the third hole and the side surface of the fourth hole. The impurities may penetrate into a portion of the first active pattern ACT1 (for example, the channel area of the first active pattern ACT1), and thus, conductivity of the channel area of the first active pattern ACT1 may increase. Therefore, a bright spot defect in which the pixel area (e.g., the first pixel area PX1) emits light regardless of a signal applied to the first active pattern ACT1 through the first contact electrode and/or the second contact electrode may occur. According to an embodiment, while the portion of the first preliminary insulating layer PIL1 and the portion of the second preliminary insulating layer PIL2 are removed, a portion the second preliminary insulating layer PIL2 overlapping the semi-transmitting area HF in the plan view may not be removed. Accordingly, the first active pattern ACT1 may not be etched. Accordingly, the particles of the first active pattern ACT1 may be prevented from being attached to a portion of the photoresist pattern PR. Accordingly, a profile of the side surface of the third hole and the side surface of the fourth hole may be uniform, and accordingly, an impurity such as moisture, oxygen, and/or the like may be prevented from penetrating into the side surface of the third hole and the side surface of the fourth hole. Accordingly, the bright spot defect may be prevented from occurring in the pixel area.

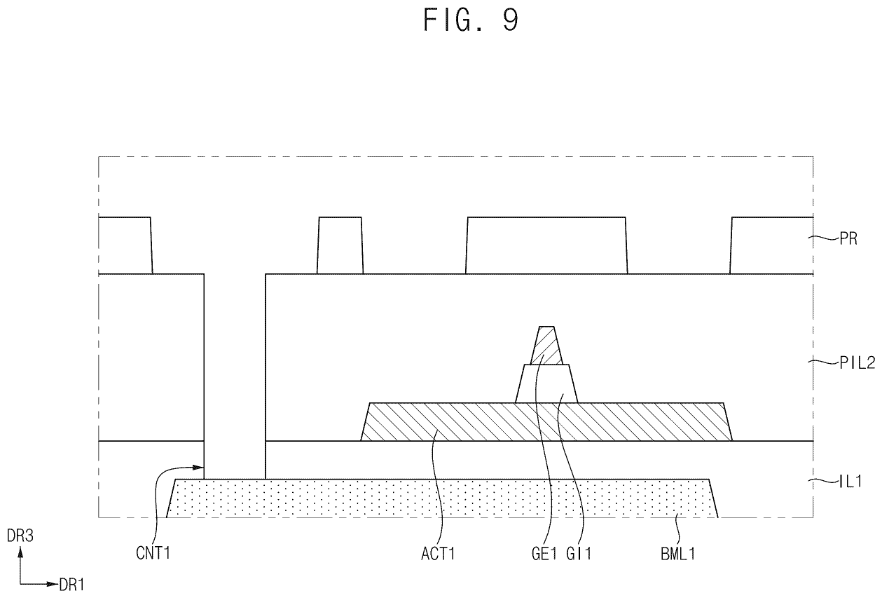

In an embodiment and referring to FIG. 9, a portion of the photoresist pattern PR may be removed to reduce a thickness of the photoresist pattern PR. For example, the portion of the photoresist pattern PR may be removed by an ashing process using oxygen (“O₂”).

In an embodiment and referring to FIGS. 9 and 10, a portion of the second preliminary insulating layer PIL2 may be removed using the photoresist pattern PR. Accordingly, the second insulating layer IL2 defining the second hole CNT2, the third hole CNT3, and the fourth hole CNT4 may be formed. A portion of the upper surface of the first active pattern ACT1 may be exposed by the third hole CNT3 and the fourth hole CNT4. In an embodiment, the portion of the second preliminary insulating layer PIL2 may be removed by a dry etching process. For example, the portion of the second preliminary insulating layer PIL2 may be removed by a dry etching process using gas including nitrogen trifluoride (“NF₃”) and oxygen (“O₂”). However, the invention is not limited thereto, and materials constituting gas for the dry etching process may be variously changed according to embodiments. The dry etching process using the gas including nitrogen trifluoride (“NF₃”) and oxygen (“O₂”) may be an isotropic etching process. In an embodiment, a portion of the photoresist pattern PR may also be removed through the dry etching process. Accordingly, a first opening PR-CNT1, a second opening PR-CNT2, and a third opening PR-CNT3 may be formed in the photoresist pattern PR. In an embodiment, a side surface of the first opening PR-CNT1 and the side surface (e.g., the side surface CNT2-S of FIG. 3) of the second hole CNT2 may be located in substantially a same plane. For example, the side surface of the second hole CNT2 may be a plane extending from the side surface of the first opening PR-CNT1. In addition, the side surface of the second opening PR-CNT2 and the side surface (e.g., the side surface CNT3-S of FIG. 3) may be located in substantially a same plane. For example, the side surface of the third hole CNT3 may be a plane extending from the side surface of the second opening PR-CNT2. In addition, the side surface of the third opening PR-CNT3 and the side surface (e.g., the side surface CNT4-S of FIG. 3) of the fourth hole CNT4 may be located in substantially a same plane. For example, the side surface of the fourth hole CNT4 may be a plane extending from the side surface of the third opening PR-CNT3.

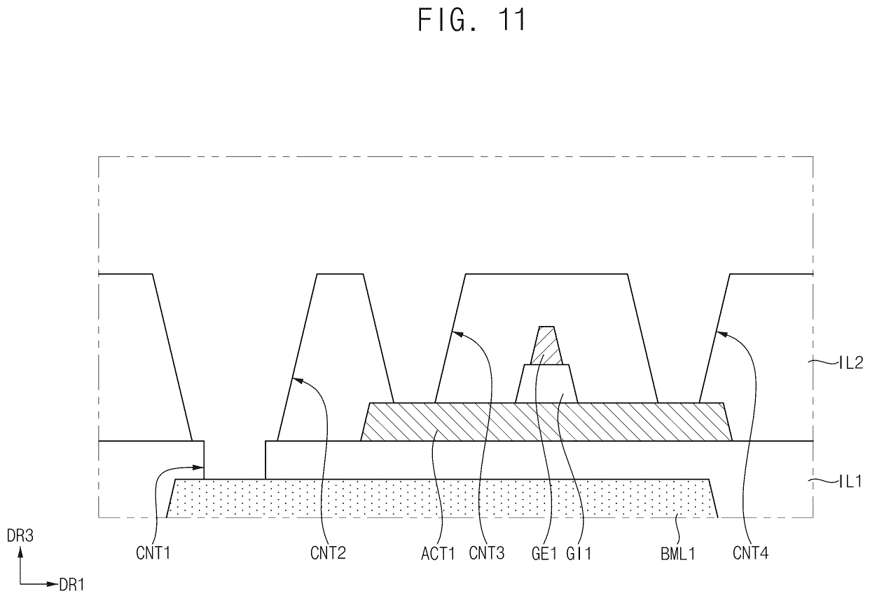

In an embodiment and referring to FIG. 11, the photoresist pattern PR may be removed. For example, the photoresist pattern PR may be removed by an ashing process.

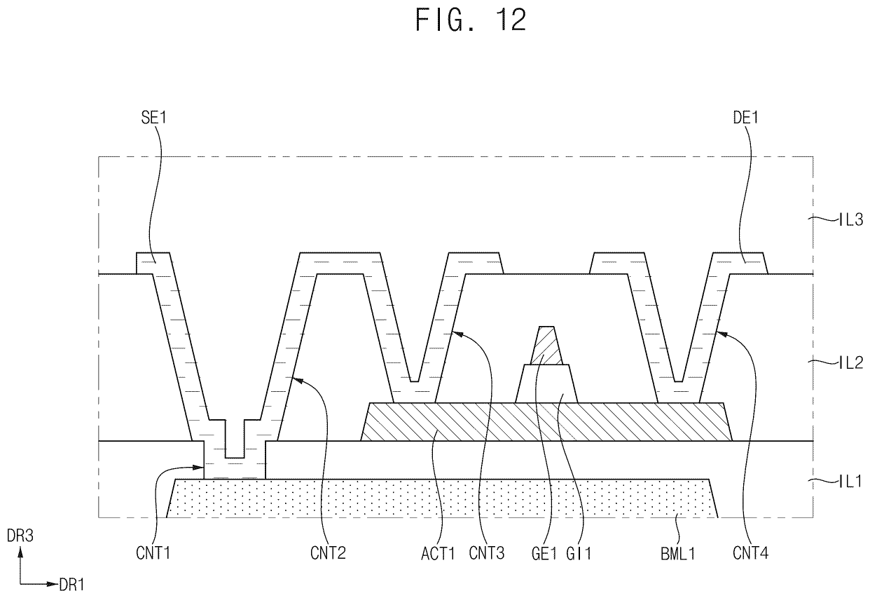

In an embodiment and referring to FIG. 12, the first contact electrode SE1 may be formed on the second insulating layer IL2. The first contact electrode SE1 may be formed to contact the first lower metal pattern BML1 through the first hole CNT1 and the second hole CNT2. In addition, the first contact electrode SE1 may be formed to contact the first active pattern ACT1 through the third hole CNT3. In addition, the second contact electrode DE1 may be formed on the second insulating layer IL2. The second contact electrode DE1 may be formed to contact the first active pattern ACT1 through the fourth hole CNT4.

In an embodiment, the third insulating layer IL3 may be formed on the second insulating layer IL2 and may be formed to cover the first contact electrode SE1 and the second contact electrode DE1.

In an embodiment, the display device (e.g., the display device DD of FIG. 1) may be applied to various electronic devices. An electronic device according to embodiments may include the above-described display device and may further include a module or device having other additional functions in addition to the display device.

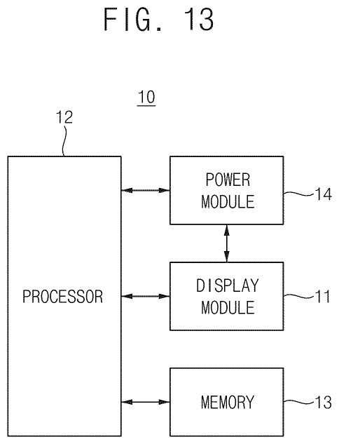

FIG. 13 is a block diagram illustrating an electronic device, according to embodiments.

In an embodiment and referring to FIG. 13, an electronic device 10 may include a display module 11, a processor 12, a memory 13, and a power module 14.

In an embodiment, the processor 12 may include at least one of a central processing unit (“CPU”), an application processor (“AP”), a graphic processing unit (“GPU”), a communication processor (“CP”), an image signal processor (“ISP”), and a controller.

In an embodiment, data information necessary for operation of the processor 12 or the display module 11 may be stored in the memory 15. When the processor 12 executes an application stored in the memory 15, an image data signal and/or an input control signal is transmitted to the display module 11, and the display module 11 may process received signal and output image information through a display screen.

In an embodiment, the power module 14 may include a power supply module such as a power adapter or a battery device, and a power conversion module that converts power supplied by the power supply module to generate power required for operation of the electronic device 10.

At least one of the components of the electronic device 10 described above may be included in the display device, according to the invention. In addition, some of individual modules functionally included in one module may be included in the display device, and others may be provided separately from the display device. For example, the display device may include the display module 11, and the processor 12, the memory 13, and the power module 14 may be provided in form of another device in the electronic device 10 other than the display device.

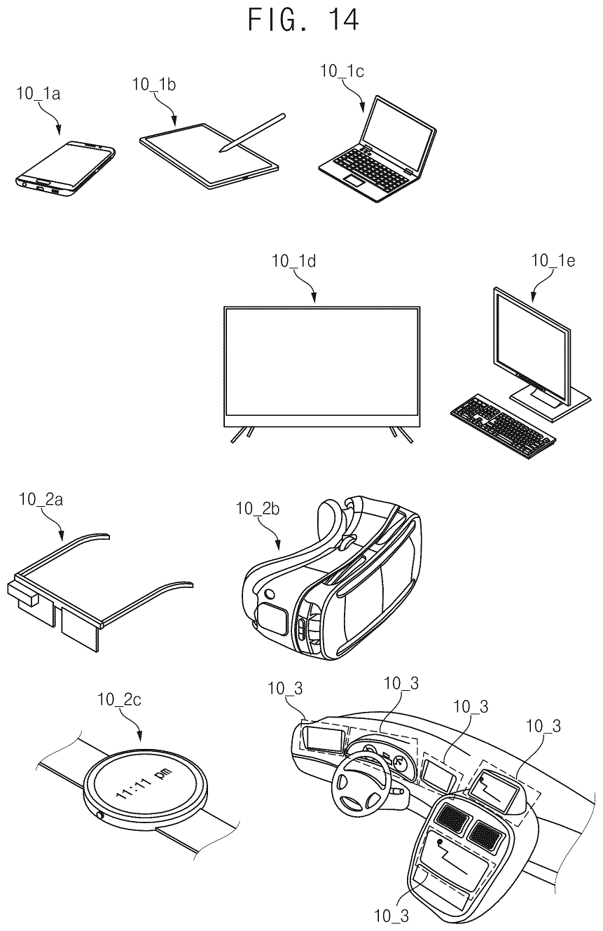

FIG. 14 is a schematic diagram of an electronic device, according to various embodiments.

In an embodiment and referring to FIG. 14, various electronic devices to which display devices are applied may include not only electronic devices for image display such as a smartphone 10_1a, a tablet PC 10_1b, a laptop 10_1c, a TV 10_1d, a desk monitor 10_1e, and/or the like, but also wearable electronic devices including display modules such as a smart glass 10_2a, a head mounted display 10_2b, a smart watch 10_2c, and/or the like, vehicle electronic device 10_3 including display modules such as a vehicle's instrument panel, a center fascia, a center information display (“CID”) located on a dashboard, a room mirror display, and/or the like.

The foregoing is illustrative of embodiments and is not to be construed as limiting thereof. Although a few embodiments have been described, those skilled in the art will readily appreciate that many modifications are possible in the invention without materially departing from the novel teachings and advantages of the invention. Accordingly, all such modifications are intended to be included within the scope of the invention. Therefore, it is to be understood that the foregoing is illustrative of various embodiments and is not to be construed as limited to the specific embodiments disclosed, and that modifications to the disclosed embodiments, as well as other embodiments, are intended to be included within the scope of the invention.

What is claimed is:

1. A display device comprising:
a lower metal pattern located on a substrate;
a first insulating layer covering the lower metal pattern, wherein the first insulating layer defines a first hole exposing at least a portion of the lower metal pattern and including a first side surface forming a first angle with an upper surface of the lower metal pattern;
an active pattern located on the first insulating layer;
a second insulating layer covering the active pattern, wherein the second insulating layer defines a second hole at least partially overlapping the first hole in a plan view and including a second side surface forming a second angle which is smaller than the first angle with an upper surface of the first insulating layer; and
a first electrode located on the second insulating layer, wherein the first electrode contacts the lower metal pattern through the first hole and the second hole.

2. The display device of claim 1, wherein the second angle is equal to or greater than about 0 degrees and equal to or less than about 70 degrees.

3. The display device of claim 1, wherein the second insulating layer defines a third hole exposing at least a portion of the active pattern and including a third side surface forming a third angle which is smaller than the first angle with an upper surface of the active pattern.

4. The display device of claim 3, wherein the third angle is equal to or greater than about 0 degrees and equal to or less than about 70 degrees.

5. The display device of claim 3, wherein the first electrode contacts the active pattern through the third hole.

6. The display device of claim 3, wherein the second insulating layer defines a fourth hole exposing at least a portion of the active pattern, spaced apart from the third hole in the plan view, and including a fourth side surface and forming a third angle which is smaller than the first angle with the upper surface of the active pattern.

7. The display device of claim 6, wherein the fourth angle is equal to or greater than about 0 degrees and equal to or less than about 70 degrees.

8. The display device of claim 6, further comprising:
a second electrode located on the second insulating layer, spaced apart from the first electrode in the plan view, and contacting the active pattern through the fourth hole.

9. The display device of claim 1, wherein the second hole has an inverted trapezoidal shape in which a width of a lower surface is smaller than a width of an upper surface in a cross-sectional view, and
a width of the lower surface of the second hole is greater than a width of the first hole.

10. A method of manufacturing a display device, the method comprising:
forming a lower metal pattern on a substrate;
forming a first preliminary insulating layer covering the lower metal pattern on the substrate;
forming an active pattern on the first preliminary insulating layer;
forming a second preliminary insulating layer covering the active pattern on the first preliminary insulating layer;
removing a portion of the first preliminary insulating layer and a portion of the second preliminary insulating layer to expose at least a portion of the lower metal pattern;
removing a portion of the second preliminary insulating layer to expose at least a portion of the active pattern; and
forming a first electrode contacting the lower metal pattern and the active pattern.

11. The method of claim 10, wherein the removing of the portion of the second preliminary insulating layer to expose at least the portion of the active pattern is performed after the removing of the portion of the first preliminary insulating layer and the portion of the second preliminary insulating layer to expose at least the portion of the lower metal pattern.

12. The method of claim 10, wherein the removing of the portion of the first preliminary insulating layer and the portion of the second preliminary insulating layer to expose at least the portion of the lower metal pattern includes,
forming a photoresist layer on the second preliminary insulating layer;
placing a mask including a transmitting area, a semi-transmitting area and a blocking area on the photoresist layer;
exposing and developing the photoresist layer to form a photoresist pattern; and
removing the portion of the first preliminary insulating layer and the portion of the second preliminary insulating layer through a dry etching process.

13. The method of claim 12, wherein while the removing of the portion of the first preliminary insulating layer and the portion of the second preliminary insulating layer is in progress, a portion of the second preliminary insulating layer overlapping the semi-transmitting area of the mask in a plan view is not removed.

14. The method of claim 12, further comprising:
removing a portion of the photoresist pattern after the removing of the portion of the first preliminary insulating layer and the portion of the second preliminary insulating layer to expose at least the portion of the lower metal pattern, before the removing the portion of the second preliminary insulating layer to expose at least the portion of the active pattern.

15. The method of claim 10, wherein the active pattern is not etched during the removing of the portion of first preliminary insulating layer and the portion of the second preliminary insulating layer to expose at least the portion of the lower metal pattern.

16. An electronic device comprising:
a lower metal pattern located on a substrate;
a first insulating layer covering the lower metal pattern, wherein the first insulating layer defines a first hole exposing at least a portion of the lower metal pattern and including a first side surface forming a first angle with an upper surface of the lower metal pattern;
an active pattern located on the first insulating layer;
a second insulating layer covering the active pattern, wherein the second insulating layer defines a second hole at least partially overlapping the first hole in a plan view and including a second side surface forming a second angle which is smaller than the first angle with an upper surface of the first insulating layer;
a first electrode located on the second insulating layer, wherein the first electrode contacts the lower metal pattern through the first hole and the second hole; and
a memory configured to store data information.

17. The electronic device of claim 16, wherein the second angle is equal to or greater than about 0 degrees and equal to or less than about 70 degrees.

18. The electronic device of claim 16, wherein the second insulating layer defines a third hole exposing at least a portion of the active pattern and including a third side surface forming a third angle which is smaller than the first angle with an upper surface of the active pattern.

19. The electronic device of claim 18, wherein the third angle is equal to or greater than about 0 degrees and equal to or less than about 70 degrees.

20. The electronic device of claim 18, wherein the first electrode contacts the active pattern through the third hole.
